(19) United States
(12) Patent Application Publication
(10) Pub. No.: US 2022/0007516 A1
(43) Pub. Date: Jan. 6, 2022

(54) METHOD AND SYSTEM FOR FABRICATING FLEXIBLE ELECTRONICS

(71) Applicant: Singapore University of Technology and Design, Singapore (SG)

(72) Inventors: Shaoying Huang, Singapore (SG); Yidan Chen, Singapore (SG); Yat Siew Han, Singapore (SG)

(73) Assignee: Singapore University of Technology and Design, Singapore (SG)

(21) Appl. No.: 17/236,572

(22) Filed: Apr. 21, 2021

(30) Foreign Application Priority Data
Apr. 30, 2020 (SG) 10202004032U

(51) Int. Cl. H05K 3/12; H05K 1/03

(52) U.S. Cl. CPC H05K 3/1241; H05K 3/1291; H05K 2203/1131; H05K 1/0393; H05K 1/0386

(57) ABSTRACT

A method of fabricating at least one electronic circuit component comprises: patterning a conductive material on a fibrous substrate by aerosol jet printing in a pattern corresponding to said at least one electronic circuit component; and sintering the conductive material by hot air sintering. The fibrous substrate may be paper, for example cellulose fibre paper.

### CROSS-REFERENCE TO RELATED APPLICATION

This application claims priority from Singapore Patent Application No. 10202004032U filed Apr. 30, 2020, the disclosure of which is hereby incorporated herein by reference.

### TECHNICAL FIELD

The present disclosure relates to a method and system for fabricating flexible electronics using aerosol jet printing.

### BACKGROUND

Aerosol jet printing (AJP) has been gaining increased attention as a novel additive manufacturing technology since its invention in 2007. AJP utilizes a focused aerosol beam, which is a suspension of liquid or solid particles in a gas stream, to directly deposit materials onto a targeted substrate without using lithography or any post patterning techniques such as laser trimming. With its ability to create patterns between 10 μm and 100 μm, this bench-top technology fills up the gap between nano-scale manufacturing which relies on vapor deposition, and millimeter-scale fabrication which utilizes traditional printed circuit technologies such as gravure printing. Moreover, AJP stands out from other droplet-based metallic direct-write technologies because of its ability to create conformal patterns on top of non-planar surfaces, thereby adding additional degrees of freedom to the manufacturing of electronics components.

AJP technology has been used to fabricate various types of functioning components, such as sensors, antennas, and solar cells. It can be applied to provide compact components for wireless power transfer, metamaterials, and portable magnetic resonance imaging, for example. In AJP, the aerosols are generated in an atomizer and aerodynamically focused in a deposition head into a concentrated beam and projected onto the substrate. The deposited inks have to be cured/thermally hardened/thermally sintered to achieve high conductivity, where the sintering temperature depends on the materials of the ink and the substrate.

A challenge faced when applying AJP for fabricating conductive patterns is that the resistance of the printed trace is usually too high to be used as part of a circuit. As such, sintering is a key post-processing step to increase the conductivity. The most commonly employed technique is thermal sintering. A high sintering temperature (usually higher than 150° C. for printing on glass substrates or poreless polymers) guarantees complete removal of the liquid medium in the aerosol droplets and assists the coagulation of the metal nanoparticles for a high conductivity of the printed structure. Although AJP printing has shown many advantages and has been applied to varies applications, it is difficult to optimize the printing parameters to achieve a desired morphology or/and a high conductivity. Further, the required sintering temperature and sintering time are both high, limiting the choice of printing substrates. The substrate needs to have a heat resistance of over 250° C. to endure the sintering; such substrates are either expensive or unavailable. This prevents AJP from being low-cost and widely-used.

### SUMMARY

In a first aspect, the present invention provides a method of fabricating at least one electronic circuit component, comprising:
(i) patterning a conductive material on a flexible fibrous substrate by aerosol jet printing in a pattern corresponding to said at least one electronic circuit component; and
(ii) sintering the conductive material by hot air sintering.

In some embodiments, steps (i) and (ii) are performed iteratively. For example, steps (i) and (ii) may be performed for at least 3 iterations.

In some embodiments, said sintering is conducted at a temperature lower than a melting temperature of particles of the conductive material. For example, the sintering may be conducted at less than about 130° C. In some embodiments, the sintering is conducted at a temperature in the range between about 60° C. and about 80° C. In some embodiments, the sintering is conducted at about 80° C.

The flexible fibrous substrate may be paper, for example cellulose fibre paper.

In some embodiments, said patterning comprises applying a plurality of layers of the conductive material. For example, said patterning may comprise applying at least three layers of the conductive material.

The method may comprise, after said sintering, room temperature drying and/or room temperature cooling of the substrate. In some embodiments, the method comprises multiple cycles of sintering and room temperature drying and/or room temperature cooling.

In another aspect, the present invention provides a system for fabricating at least one electronic circuit component, comprising:

an aerosol jet printing device;

a hot air sintering module; and

at least one controller in communication with the aerosol jet printing device and the sintering platform;

wherein the at least one controller is configured to:

cause the aerosol jet printing device to perform a printing operation comprising patterning a conductive material on a flexible fibrous substrate in a pattern corresponding to said at least one electronic circuit component; and

cause the hot air sintering module to perform a sintering operation to sinter the conductive material.

In some embodiments, the at least one controller is configured for iterative performance of the printing and sintering operations. For example, the at least one controller is configured for at least 3 iterations of the printing and sintering operations.

In some embodiments, said sintering operation is conducted at a temperature lower than a melting temperature of particles of the conductive material. For example, the sintering operation is conducted at less than about 130° C. In some examples, said sintering operation is conducted at about 80° C.

In some embodiments, the patterning operation performed by the system comprises applying a plurality of layers of the conductive material. For example, said patterning operation may comprise applying at least three layers of the conductive material.

### BRIEF DESCRIPTION OF THE DRAWINGS

Some embodiments of methods and apparatus for fabricating flexible electronics, in accordance with present teachings will now be described, by way of non-limiting example only, with reference to the accompanying drawings in which:

FIG. 1 is a block diagram of an example system for fabricating flexible electronics;

FIG. 2 is a schematic illustration of an example aerosol jet printing module of the system of FIG. 1;

FIG. 3(a) is a schematic illustration of an example sintering module of the system of FIG. 1;

FIG. 3(b) shows an example scan pattern of an air gun of the sintering module of FIG. 3(a) during a sintering operation;

FIG. 4 is a flow diagram of an example of a method for fabricating flexible electronics;

FIG. 5 shows (a) 3D structure of a test strip on 80 gsm cellulose paper and (b) optical image of the printed test strip after sintering;

FIG. 6 shows SEM images of printed structures produced by a method according to example embodiments: (a) the top view, and (b) the cross-sectional view with the inter-diffused conductive layers (the silver on top and the silver in fiber pore as labelled); the SEM images of a 80 gsm paper, (c) the top view, and (d) the cross-sectional view; and the SEM images of a 160 gsm paper, (e) the top view, and (f) the cross-sectional view; the SEM image of the silver nano-flake (i.e., silver nanoparticle) ink used with (g) 16,000× magnification, and (h) 43,000× magnification;

FIG. 7 shows measured sheet resistance of printed structures when different numbers of layers are finished following an optimized sintering sequence SQ1 on 80 gsm and 160 gsm cellulose paper substrates, and following an alternative sintering sequence on 80 gsm cellulose paper substrate;

FIG. 8 shows SEM images of the top view and cross-sectional view of the printed structures when different numbers of layers are finished (i.e., printed and sintered) in an optimized sintering sequence SQl;

FIG. 9 shows estimated thickness of the printed structures after each layer is printed or sintered, the estimations being based on the SEM images of the structures;

FIG. 10 shows measured conductivity of the printed structures following the optimized sintering sequence with (a) the sintering temperature (Ts) set to be 60° C. and 80° C.; (b) the total sintering time (ts) set to be 1 min, 5 min, 10 min, and 15 min; (c) the sintering speed ((vs) set to be 1 mm/s and less than 1 mm/s;

FIG. 11 shows measured conductivity of the printed structures following the optimized sintering sequence with (a) the net carrier flow rate (RC) set to be 150 sccm, 75 sccm, 50 sccm, and 35 sccm; (b) the sheath gas flow rate (RS) set to be 70 sccm, 35 sccm, 25 sccm, and 15 sccm;

FIG. 12(a) is a flow diagram of an alternative sintering sequence based on the hot-air sintering process (named SQ2);

FIG. 12(b) shows the measured resistance per unit length of the printed structures when different numbers of layers are finished in both SQ1 and SQ2;

FIG. 13 shows SEM images of the top view and cross-sectional view of the printed structures when different numbers of layers are finished (i.e., printed and sintered) in the alternative sequence, SQ2;

FIG. 14 shows measured sheet resistance of the printed structures following SQ2 with (a) a room temperature drying time (td) set to be 1 h, 3 h, 12 h, and 24 h; (b) a room temperature cooling time (tc) set to be 0 min, 30 min, 60 min, and 90 min;

FIG. 15 shows SEM images of the top view and cross-sectional view of the printed structures when different numbers of layers are finished (i.e., printed and sintered) in the optimized sequence, SQ1, on 160 gsm cellulose fiber papers; and

FIG. 16 shows normalized sheet resistance with respect to the values of the sintered first layer of the 2 mm test strip.

### DETAILED DESCRIPTION

In general terms, embodiments of the present disclosure provide methods and systems for fabricating flexible electronic components, in which aerosol jet printing is used to apply a conductive material to a flexible fibrous substrate, followed by hot air sintering of the conductive material. Embodiments enable a relatively low sintering temperature to be used for a short sintering time, thus enabling higher throughput production, while maintaining high conductivity of the printed electronic components. A high adhesion of the printed structure to the substrate is also possible.

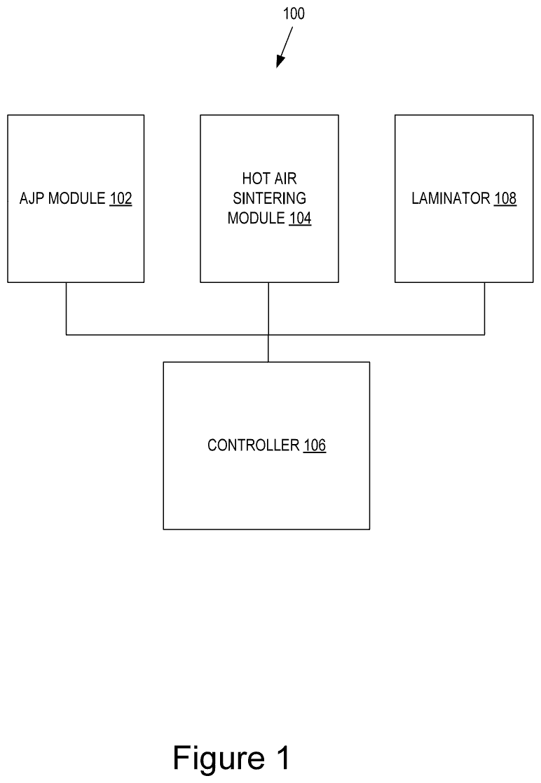

Referring initially to FIGS. 1 to 3, a system 100 for fabricating flexible electronics comprises an air jet printing (AJP) module 102, a hot air sintering module 104, and a laminator 108, each in communication with at least one controller 106. The AJP module 102, hot air sintering module 104 and laminator 108 may each be controlled by a separate controller 106, or all modules may be controlled by a single (common) controller, for example.

In some embodiments, the controller 106 (or each such controller) may be a computer system based on a 32 bit or a 64 bit Intel architecture, and the methods performed by the system 100 under the control of controller 106 may be implemented in the form of programming instructions of one or more software components or modules stored on non-volatile (e.g., hard disk) computer-readable storage associated with the computing device. At least parts of the software modules could alternatively be implemented as one or more dedicated hardware components, such as application-specific integrated circuits (ASICs) and/or field programmable gate arrays (FPGAs).

The computing device may include one or more of the following standard, commercially available, computer components, all interconnected by a bus: random access memory (RAM); at least one computer processor; and a network interface connector (NIC) which connects the computer device to a data communications network and/or to external devices, such as the AJP module 102, hot air sintering module 104, and laminator 108.

In some embodiments, the controller 106 may comprise one or more programmable logic controllers (PLCs) that are programmed to control the AJP module 102 and/or hot air sintering module 104 and/or laminator 108 to perform methods according to the present disclosure.

The AJP module 102 is used to apply a conductive material in a desired pattern to the fibrous substrate, while the hot air sintering module 104 is subsequently used to sinter the conductive material. The laminator 108 is optional, and if present, is used to laminate the substrate to protect it after the printing and sintering operations have been performed. The substrate may initially be presented at the AJP module 102 for application of one or more layers of conductive ink, and then transported (e.g. using standard inline fabrication machinery) to the sintering module 104 for curing/sintering of the conductive ink. The sintering module 104 may be operable to return the substrate to the AJP module 102 for further printing of conductive ink, followed by further sintering operations, for example.

When the droplets leave the nozzle of the AJP module 102 and are deposited onto the fibrous substrate, due to the porous nature of the substrate, they diffuse into the substrate instead of accumulating on top of the substrate. Moreover, during the process of diffusion, the liquid media of the droplets are absorbed by the intrafiber and interfiber pores of the substrate. The diffusion saturates as the number of printing layers increases. After printing, hot-air sintering is proposed to evaporate the liquid media of the droplets. When the evaporation is complete (i.e., no liquid media remains), boundary growth and necking formation between adjacent particles of the conductive material take place, forming a smooth conducting layer significantly below the melting point of the particles. Without wishing to be bound by theory, in at least some embodiments it is thought that this is due to melting point depression of nanoparticles and the Oswald ripening effect. Because of the absorption that takes place before the sintering, the conducting layer can form when the sintering temperature is relatively low and the sintering time is relatively short. Further, the printed structures fabricated according to methods and systems of embodiments of the present disclosure have high conductivity and high adhesiveness that are closely linked to the morphology of the structure.

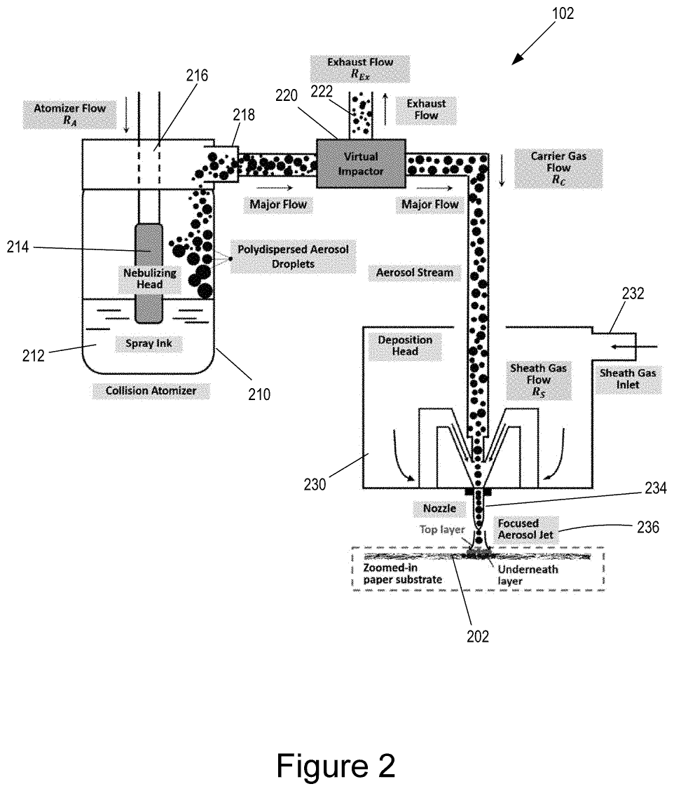

FIG. 2 shows a schematic illustration of an example AJP module 102 for printing a pattern of one or more electronic circuit components on a flexible substrate, in this case a paper substrate 202, where a zoomed-in cross-sectional view of the paper substrate 202 is shown at the bottom. In one example, the AJP module 102 may be an Optomec Aerosol Jet 5X system (Optomec, Inc., Albuquerque, N. Mex.). The AJP module 102 comprises an atomizer 210 containing a reservoir of a conductive ink 212. The atomizer 210 comprises a nebulizing head 214 that is in contact with the ink 212, and which is provided with a flow of gas at a rate RA.

The conductive ink 212 may be any ink compatible with aerosol jet printing systems. In some embodiments, the ink may contain metallic nanoparticles, such as silver nanoparticles. One such example ink is silver flake ink, such as that produced by Novacentrix (Austin, Tex.). Many other conductive inks may be used in embodiments of the present disclosure. For example, a conductive ink may comprise particles of one or more of gold; platinum; nickel; copper; and aluminium. In some embodiments, the conductive ink 212 may comprise non-metallic conductors such as single-wall or multi-wall carbon nanotubes, or PEDOT:PSS.

Polydispersed aerosol droplets of the ink 212 are produced and exit the atomizer 210 at an outlet 218, and flow to a virtual impactor 220. The virtual impactor 220 acts to draw away droplets below a certain size, through exhaust outlet 222 at an exhaust flow rate REM, to prevent clogging. The remaining flow passes at a flow rate Rc (=R_{A}−R_{Ex}) to a deposition head 230 that comprises a sheath gas inlet 232 and a nozzle 234. The sheath gas inlet 232 is used to provide a flow of sheath gas at flow rate R_{S} to control the stream of droplets leaving the nozzle 234 so as to produce a focused aerosol jet 236 that is applied to the substrate 202. The sheath gas flow may be controlled so that the size of the aerosol droplets leaving the nozzle 234 are matched to the pore size of the fibrous substrate 202, for example.

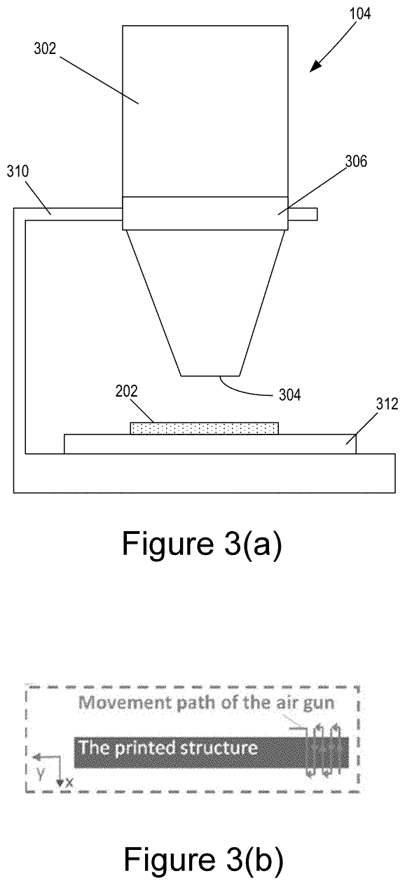

FIG. 3 is a schematic illustration of an example of a hot air sintering module 104. The hot air sintering module 104 comprises a hot air gun having a barrel 302 comprising electrical heating elements for heating air to a desired temperature, and a nozzle 304 for ejecting the heated air. The hot air gun is mounted via a holder 306 to a frame 310 such that the nozzle 304 is supported above a translation stage 312 that is movable relative to the frame 310, both in the x-y plane, and in the z-direction (i.e. to change the distance between nozzle 304 and upper surface of translation stage 312). For example, the translation stage 312 may be a Cartesian platform (LINBOU Nearfield, Shenzhen, China).

The fibrous substrate 202, with one or more layers of conductive material applied, may be positioned on the translation stage 312 below the nozzle 304 so that hot air can be applied to the substrate 202 (for example, in a scan pattern such as a zigzag pattern) to sinter the conductive material.

The hot air sintering module 104 may also comprise an air temperature probe (not shown) to monitor the temperature of air reaching the substrate 202, and a gradient meter mounted to the hot air gun (e.g. to a top surface of the barrel 302) to ensure that airflow from the nozzle 304 reaches the substrate 202 at substantially normal incidence.

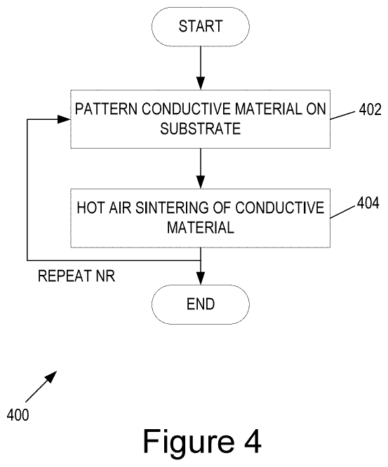

FIG. 4 is a flow diagram of a first example of a method for fabricating an electronic circuit component according to embodiments of the present disclosure.

The method 400 (also referred to herein as SQ1) comprises a first operation 402 of patterning a conductive material on a flexible fibrous substrate, such as paper, by aerosol jet printing in a pattern corresponding to said at least one electronic circuit component. Operation 402 may be carried out by AJP module 102 under the control of controller 106. For example, first operation 402 may comprise applying silver flake ink, or another metallic or non-metallic nanoparticle-containing conductive ink, to the fibrous substrate by aerosol jet printing.

The method 400 also comprises a second operation 404 of hot air sintering of the conductive material applied to the substrate. Operation 404 may be carried out by hot air sintering module 104 under the control of controller 106.

The sintering operation 404 is carried out at a certain temperature (Ts) and speed (vs), for a certain time (ts).

For example, the sintering may be conducted at a temperature Ts that is lower than a melting temperature of particles of the conductive material. For example, the air gun of sintering module 104 may be controlled to produce hot air having temperature of less than about 130° C. as measured at the substrate. In some examples, the sintering is conducted at about 80° C.

The sintering speed, vs, is the speed of the relative movement between the air gun and the substrate having the conductive material applied. The sintering speed may be estimated using the total length of the movement path of the air gun (covering both the x and y-directions) divided by the sintering time. In some embodiments, the translation stage 312 of the sintering module 104 may be controlled such that the nozzle 304 of the air gun travels above the printed (patterned) structure of the conductive material.

The second operation 404 is conducted for a time ts after applying one layer of aerosol jet printing to the substrate. It will be appreciated that in some embodiments, multiple layers of printing may be applied (during first operation 402), prior to conducting the second operation 404. In some embodiments, ts is at least 10 minutes.

In some embodiments, the first and second operations 402, 404 may be conducted iteratively (NR times, where NR>1). It has been found that iteration of the first and second operations produces lower sheet resistance and higher conductivity, with four iterations producing optimal results.

The hot-air sintering time (ts) and the number of iterations (NR) may be optimized to produce an optimal conductivity of the printed structure. In some embodiments, the optimal ts and NR and 10 min and 4, respectively. The optimal sintering speed is determined by a requirement that the hot-air gun goes through the printed structure one round in both the x and y-directions within ts (10 min).

### Experimental Results and Optimization of Printing and Sintering Parameters

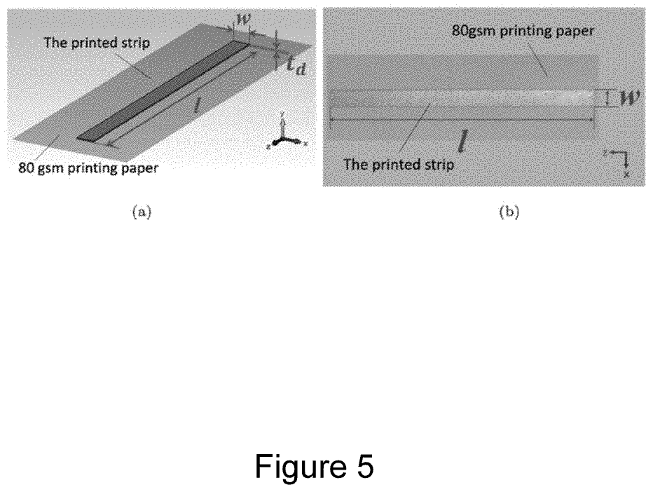

A metallic strip, as shown in FIG. 5(a), with a length of 50 mm and a width of 2 mm was printed on 80 gsm paper according to the method 400. For printing, the sheath gas flow rate, atomizer gas flow rate, and exhaust flow rate were set to be 35 sccm, 1075 sccm, and 1000 sccm, respectively. The pressure of the carrier gas was 75 sccm. The diameter of the nozzle was 300 μm. The standoff height between the nozzle head and the substrate was set to be 5 mm. The ink used was the Metalon HPS-108AE1 silver flake ink (Novacentrix, Austin, Tex.) with particle sizes of 0.4 μm and 0.7 μm. The printing bed was kept at room temperature (25° C.) without additional heating. The printing speed was maintained at 8 mm/s.

For the hot-air sintering, the distance between the air outlet 304 and the substrate 202, d, was set to 15 mm. The sintering time was set to be 10 min, and the hot-air gun went through the printed structure in both the x- and the y-direction with a movement path shown in FIG. 3(b). Based on the dimension of the metallic strip and the total length of the movement path for one round, 10 min of sintering time (ts=10 min) results in a sintering speed of equal to or less than 1 mm/s, i.e., vs≤1 mm/s. The temperature of the hot air (Ts) was set at 80° C., and the temperature of the air reaching the paper substrate was monitored by an air temperature probe, Keysight U1183A.

The sintering sequence shown in FIG. 4 was followed. When the paper substrate 202 is removed from the AJP printer 102 for sintering or removed from the sintering platform 104 for resuming printing, potential damage of the printed structure is minimized by using a much larger substrate compared to the size of the printed structure, to minimize the deformation of the region under the printed structure. Meanwhile, folding of the substrate is avoided where possible. Moreover, due to the diffusion of the droplets into the paper substrate based on the proposed fabrication method, the bonding between the printed structure and the substrate is strong to withstand deformation (if any) during the transportation process between the printer 102 and the sintering platform 104. To ensure the alignment of the nozzle 234 and the printed structure on substrate 202 each time when the printing 402 is resumed after the sintering 404, the locations of the four corners of the paper substrate 202 were marked on the base of the Optomec printer 102. Both the printing and sintering parameters are the optimal ones. The optimization of the parameters will be presented below.

FIG. 5(b) shows a photo of a printed strip. The resistance of the strip (R) was measured along the z-direction by using Keysight U1253B multimeter and the sheet resistance, i.e., the resistance per unit area (Rs) was calculated, Rs=Rw/ι. The measured sheet resistance is 1.13×10⁻² Ω/m² which is equivalent to a conductivity of 7.14×10⁶ S/m. The sheet resistance is 10 times less compared to the traditional AJP printing using silver metal ink on glass substrate with 100 mW laser sintering. The conductivity of the printed structure using the proposed approach is close to that of bulk metals, which allows for the printing of circuit components at different frequencies using this printing technique, e.g., traces at a relatively low frequency, and transmission lines, planar filters, or patch antennas at a relatively high frequency (e.g., radio frequency, microwave frequency, or above).

The conductivity was estimated based on an estimation of the cross-sectional area of the printed structure, which will be explained in detail in the next section.

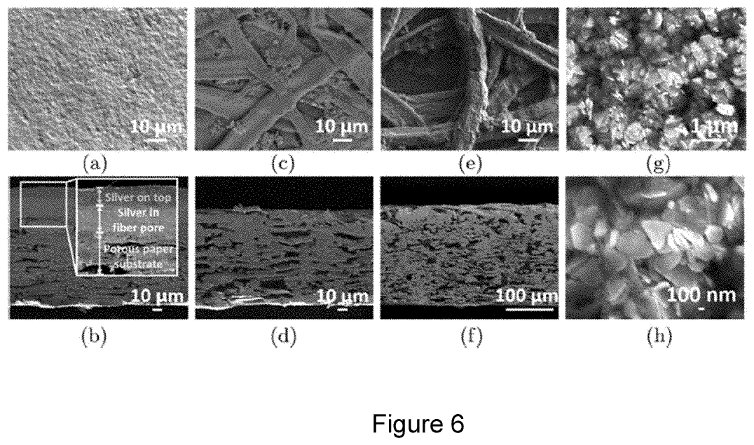

FIGS. 6(a) and (b) show the top view and cross-sectional view of the SEM images of the printed strip, respectively. For a comparison, FIGS. 6(c) and (d) respectively show the corresponding SEM images of a bare 80 gsm paper without printing, and FIGS. 6(g) and (h) show the SEM images of the silver nano-flake (i.e., silver nanoparticle) ink used in the printing with a magnification of 16,000 times and 43,000 times, respectively.

As shown in FIG. 6(a), a smooth surface is observed, which indicates a smooth and continuous layer of silver coalescence formed on top of the cellulose fibers. The smoothness becomes more obvious when it is compared to either the SEM images of a bare paper without printing shown in FIG. 6(c) or those of bare silver nano-flake ink shown in FIGS. 6(g) and (h). This smooth and continuous layer of silver coalescence can be seen from the cross-sectional view in FIG. 6(b) as well.

In FIG. 6(b), the smooth layer on the top is the silver layer. It has a transition changing from dark grey to light grey where the dark grey layer corresponds to the one on top of the paper substrate, whereas the light grey one corresponds to the silver coalescence formed into the cellulose fibers of the paper substrate. They are the inter-diffused conductive layers that contribute to the adhesiveness of the printed structure. Under the smooth silver layer is the porous paper substrate.

Comparing the cross-sectional view of the printed structure and that of bare paper in FIGS. 5(b) and (d), respectively, the smooth layer at the top is the result of aerosol jet printing and sintering. The sample with the printed structure is relatively thicker due to the silver layer on top of the substrate. For the pattern fabricated with the proposed approach, this smooth and continuous layer of silver coalescence on top of the cellulose fibers indicates a high density of percolation pathways for electrons to move through, which leads to a high conductivity of the structure. The light grey silver layer in the paper in between the dark grey layer on the top and the porous paper substrate as a transition contributes to the adhesiveness of the printed structure to the substrate.

Commercial printing papers are cellulose-fiber-based. They are porous, as can be clearly seen from the SEM images of 80 gsm printing paper (the top and from the side in FIGS. 6(c) and (d), respectively) and those of 160 gsm printing paper (the top and from the side in FIGS. 6(e) and (f), respectively).

In the top view of 80 gsm and 160 gsm paper in FIGS. 6(c) and (e), obvious fibers can be seen. In the following contents, the measured resistance and the SEM images of the printed structures that display the morphological will be presented, and their relation will be shown. The effect of the repetition time of the proposed hot-air sintering sequence (NR) will be shown at the same time. Following that, the optimization of the two types of parameters, the sintering parameters (Ts, vs, and ts) and the AJP PCM ones (RS, RA, and REx), will be shown by examining their effects on the printing quality in terms of conductivity. Moreover, the influences of the sintering sequence and those of the types of paper used as the substrate on the quality of the proposed printing will be detailed.

Relation between the Resistance and Morphology of Printed Structures and the Effects of NR

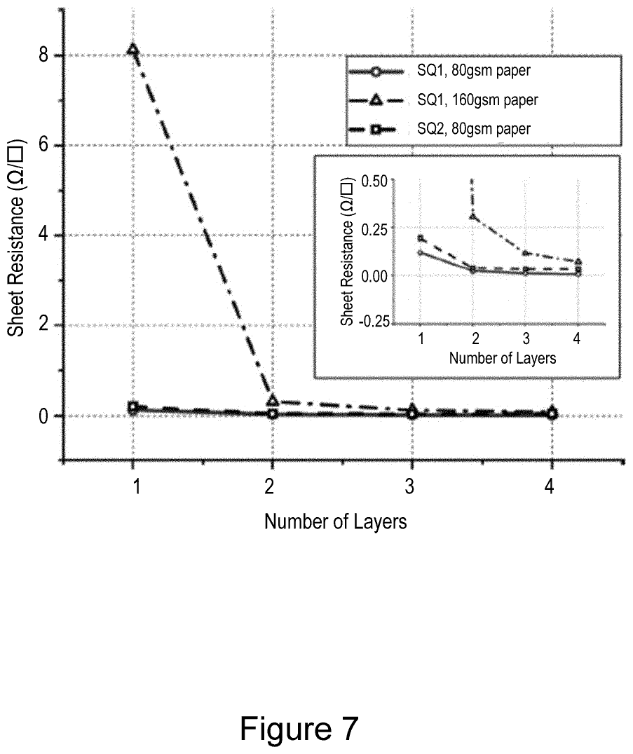

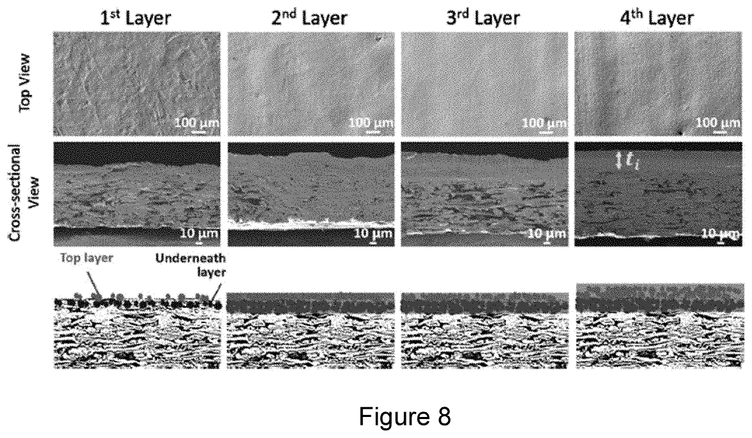

In order to investigate the relation of the aerosol jet printing, the proposed hot-air sintering, and the resultant conductivity of the printed structure, the correlation between the resistance of the printed structures and their morphology was studied. The resistance of the test strips was measured, the resistance per unit square was calculated, and their SEM images were taken when different numbers of layers were finished following the proposed sintering sequence. FIG. 7 shows the measured resistance per unit area versus the number of layers, and FIG. 8 shows the corresponding SEM images of the printed structures after sintering, including the top views (the first row) and the cross-sectional views (the second row). As shown in FIG. 7, the resistance per unit area decreases significantly when more layers are printed and sintered. The decrease slows down after an accumulation of three layers. The decrease is reduced to 9.6% when the 4th layer was printed. This implies a significant increase in conductivity of the printed structure when the number of the printed layers increases, and a saturation at three layers.

The morphologies of the printed structures displayed in the SEM images in FIG. 8 exhibits a close correlation to the measured resistance. As shown in the first column in FIG. 8, when one layer was printed and sintered, obvious fibers and pores can be seen in the top view, and no distinguishable smooth layer can be observed at the top of the cross-sectional view. When one layer was printed, the droplets diffuse directly into the paper substrate, and there are not enough silver nanoflakes sitting on top of the substrate or in the substrate during the sintering process to form a smooth conducting layer. This is illustrated in the first sub-figure in the third row of FIG. 8. As a result of a lack of a continuous conducting layer, the resistance of the printed structure is high. When the 2nd and the 3rd layers were printed onto the paper substrate, more pores were filled up, the fibers were covered, and a smooth conducting layer was gradually formed. As can be seen in the top view of the second column in FIG. 8, the number of pores and bare fibers are reduced significantly compared to those in the first column, although there are still scattered pores and fibers that can be distinguished.

In the cross-sectional view of the second column, the top profile of the structure is not smooth, which corresponds to the uneven surface shown in the top view. On the other hand, the droplets that diffused into the substrate accumulated, starting to form a smooth layer after sintering. The process is illustrated by the second sub-figure of the third row. This corresponds to a considerable decrease in the measured resistance in FIG. 7 for the case of two layers. On top of the 2nd layer, the smoothness of the top layers was further greatly improved when the 3rd layer was printed and sintered. This can be observed in both the top view and the cross-sectional view in column three. As shown in the top view, the majority of the pores are filled up and most of the fibers are covered.

In the cross-sectional view, the top profile of the structure is smooth, which indicates that the droplets were saturated in the substrate and accumulated on top of the substrate, forming a smooth layer there after sintering. The 3rd sub-figure of the third row illustrates this. As a result of the smooth conducting layer forming on top and into the substrate, the resistance further decreases considerably, as shown in FIG. 7. For the printing of the 4th layer, it is an additional improvement of the smoothness of the top conducting layer. As a conducting layer had already been formed after the printing of three layers, both the improvement of the smoothness and a reduction in resistance are subtle when the 4th layer was printed and sintered, which can be seen in the 4th column in FIG. 8 and in FIG. 7, respectively. The incremental improvement of the smoothness of the top layer is illustrated in the fourth sub-figure of the 3rd row in FIG. 8. Based on the experimental results above, the optimal NR is three.

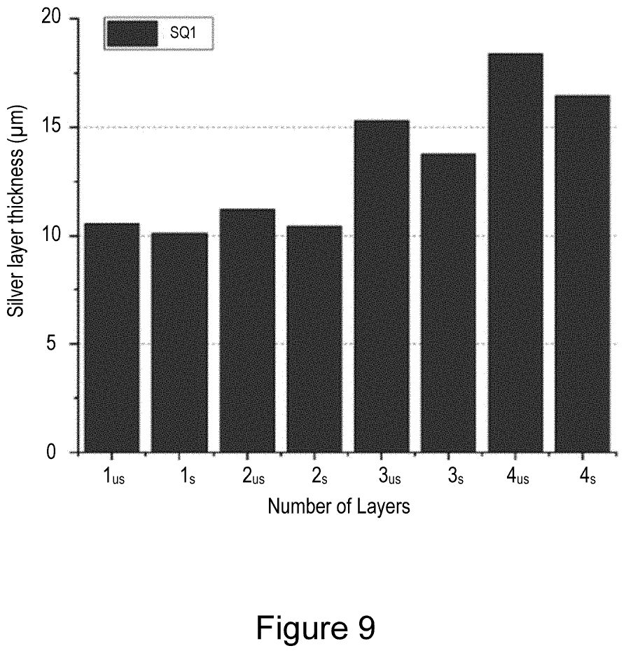

With the proposed printing approach, a smooth and dense conducting layer is formed after three layers of printing. To estimate the conductivity of the printed structure after each layer of printing, the thickness of the printed structure is estimated by calculating the average of the measured thickness at different locations along the cross-section of the test strip. The arrow at Row 2 Column 4 in FIG. 8 shows the thickness of a specific location, ti, after four layers were printed. FIG. 9 shows the estimated thickness of the printed structures after each layer of printing (before sintering and denoted using the subscript ‘us’ standing for unsintered) or sintering (denoted using the subscript ‘s’) based on the SEM images. As shown, the thickness of the structure increases as more layers were printed. It is noticed that the increase of the structure thickness between the first and second layer is much less compared to that between the second and third layer, or that between the third and fourth layer. This is due to the diffusion process when the droplets arrive at the paper substrate. Meanwhile, comparing the thickness of the structure with the same number of layers before and after sintering, it is observed that the value is reduced after the sintering, which is due to the evaporation of the liquid medium. For the four-layered printed structure, the calculated average thickness is 16.45 μm; therefore, the conductivity is 7.14×10⁶ S/m based on the measured sheet resistance of 1.13×10⁻² Ω/sq.

### The Effects of the Sintering Parameters (Ts, ts, and vs)

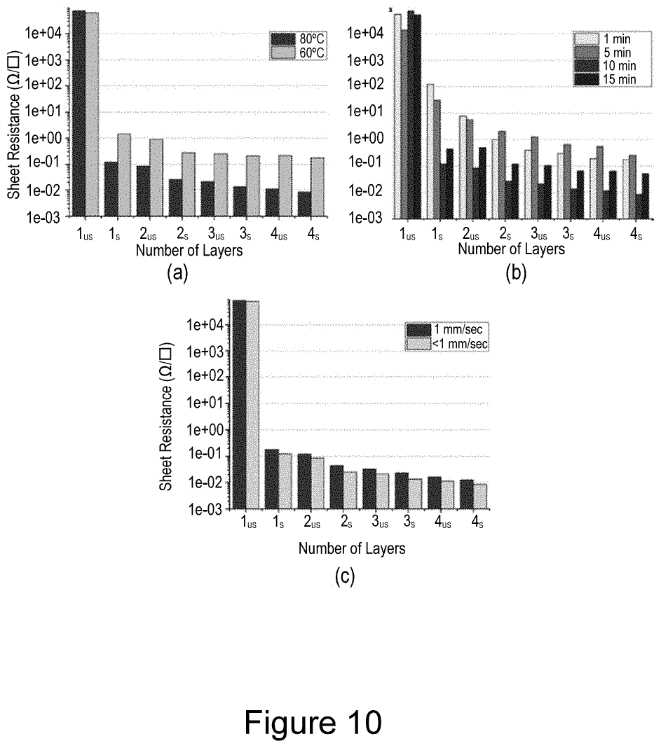

The parameters of the proposed sintering process, the sintering temperature, sintering time, and sintering speed play an important role in the conductivity of the printed structure. Their optimal values are set at 80° C., 10 min, and <1 mm/s, respectively. FIGS. 10(a)-(c) show the sheet resistance versus the number of printed layers when Ts, ts, and vs varies, respectively. FIG. 10(a) shows a comparison when the sintering temperature was set to 80° C. and 60° C. The other two parameters, ts and vs, were set to be 10 min and <1 mm/s, respectively. As can be seen, 80° C. leads to a much lower resistance at each layer of printing compared to 60° C. This is because a relatively high temperature accelerates the evaporation of the liquid medium of the droplets as well as the boundary growth and necking formation between adjacent particles. When Ts was increased to be more than 80° C., the paper substrate becomes brittle, losing its strength and elasticity.

To investigate the effect of sintering time on the quality of printing, fabrication processes with different sintering times were conducted. The other two parameters, Ts and vs, were set to be 80° C. and<1 mm/s, respectively. FIG. 10(b) shows a comparison when the sintering time was varied from 1 min to 15 min. 10 min of sintering time leads to the lowest resistance. Shorter duration, i.e., 1 min or 5 min, may lead to an inadequate evaporation of the liquid medium of the droplets or incomplete boundary growth and necking formation of adjacent metal nano-flakes. The time longer than 10 min may lower the elasticity of the paper substrate on top of a relatively higher resistance. FIG. 10(c) shows the results when the sintering speed was set to be 1 mm/s and less than 1 mm/s (10 min of sintering time for going through the printed strip once, a span in the x-direction of about 6 mm, the length of the strip varies from 30 mm to 94 mm that corresponds to a vs ranging from 0.32 mm/s to 1 mm/s). The other two parameters, Ts and ts, were set to be 80° C. and 10 min, respectively. As can be seen in FIG. 10(c), a slower sintering leads to a relatively low resistance. This indicates that it takes time for heat to be delivered from the heat source and penetrate into the deposited layer along the z-axis through conduction for the nano-flakes to melt and form a smooth layer.

### The Effects of the AJP PCM (RS, RA, REx)

The effects of the AJP printer 102 setup in terms of the sheath gas flow rate (RS), atomizer gas flow rate (RA), and exhaust flow rate (REx) on the quality of the printed structure in terms of the conductivity are investigated.

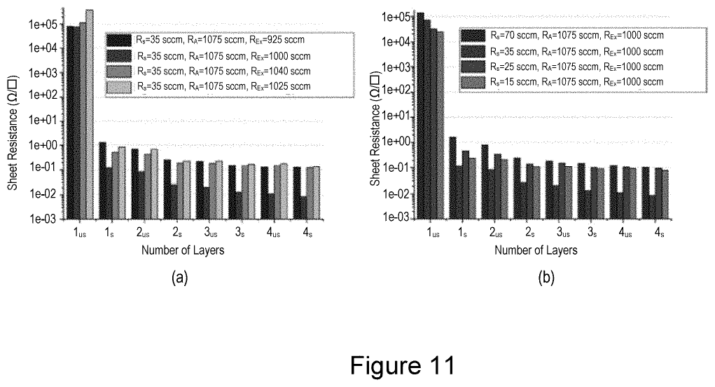

FIG. 11 shows the measured sheet resistance of the printed structures versus the number of printed layers using SQ1 with Ts=80° C., vs <1 mm/s, and ts=10 min when RS, RA, and REx were varied. As shown in FIG. 11(a), when REx was increased from 925 sccm to 1000 sccm, while RA was set to 1075 sccm and Ps was kept at 35 sccm, i.e., the carrier gas flow rate decreases from 150 sccm to 75 sccm, the resistance of the printed structures is much lower. In addition, during the printing process, it was observed that with a higher carrier gas flow rate (>75 sccm), the nozzle (300 μm in diameter) started to display signs of blockage after 20 min of printing, and the system had to be disassembled for cleaning to maintain the printing quality. In contrast, when the carrier gas flow rate was set to be 75 sccm, the cleaning process was only required after more than 1 hour of printing, and thus significantly reduced the total fabrication time. When the REx was further increased to 1025 sccm and 1040 sccm, i.e., Rc is reduced to 50 sccm and 35 sccm, respectively, as shown in FIG. 11(a), it is observed that a decrease in the carrier gas flow rate did not lead to a lower resistance. A carrier gas flow rate of 75 sccm is the optimal one within the range of values studied. Other values are also possible, for example between about 60 sccm and 90 sccm, or between about 65 sccm and 85 sccm, or between about 70 sccm and 80 sccm.

The possible reason for this could be that when the carrier gas flow rate is too high (>75 sccm), although higher density of aerosol droplets are generated by the nebulizing head, the droplets hit the substrate with higher speed and momentum, and thus the diffusion saturation threshold increases. The formation of the continuous conductive layer would then be hindered and a higher resistance as shown in FIG. 11(a) is observed. When the carrier gas flow rate decreases below a certain level (<75 sccm), however, not enough aerosol droplets with silver nano-flakes are generated, which leads to a underdeveloped conductive layer with the same number of layers of printing, and an increase in the sheet resistance. On the other hand, when RA and REx were kept at 1075 sccm and 1000 sccm, respectively, and Rs was increased from 35 sccm to 70 sccm, as shown in FIG. 11(b), a lower sheath gas flow rate leads to a much lower resistance. To the other end, when Rs decreases from 35 sccm to 25 sccm and 15 sccm, much higher resistance is observed. A 0-sccm sheath gas flow rate would result in problems of overspray and inconsistent printing, rendering an inconclusive test outcome. A sheath gas flow rate of 35 sccm is an optimal value that gives the lowest sheet resistance. In some embodiments, the sheath gas flow rate may be between about 28 sccm and 42 sccm, or between about 30 sccm and 40 sccm, or between about 32 sccm and 38 sccm, or between about 34 sccm and 36 sccm.

### The Effect of the Sintering Sequence

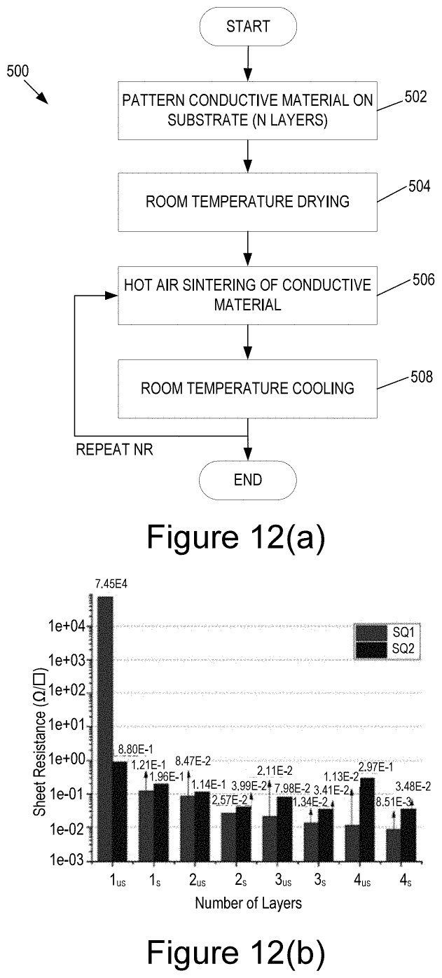

The effect of the sintering sequence is examined. Besides the proposed sintering sequence as shown in FIG. 4, the proposed hot-air sintering can be done after all the layers are printed. FIG. 12(a) shows such an alternative sintering sequence 500, referred to herein as SQ2, for AJP printing on cellulose fiber paper when a high conductivity can be obtained.

As shown in FIG. 12(a), multiple layers of the conductive material are applied in succession in the desired pattern at operation 502. This is followed at operation 504 by room temperature drying for a time period of td. After the drying operation 504, a hot-air sintering operation 506 is conducted for ts (ts was set to be 10 min). This is followed by a room temperature cooling operation 508, for a time period of tc. The combination of sintering 506 and cooling 508 is repeated NR times before the method 500 ends. The optimal values for td, tc, and NR are 24 h, 60 min, and 4 where the optimizations will be presented in the later part of this sub-section. With the optimal values where a low resistance of the printed structure can be obtained, the total processing time is 25 h and 40 min which is much longer than that in SQ1 (40 min).

In order to form a smooth silver conducting layer from the accumulated droplets from the nozzle 234 by the proposed relatively low temperature hot-air sintering process 400 or 500, an evaporation of the liquid medium of a droplet is necessary. This process is greatly accelerated when the hot-air sintering is conducted after each layer is printed as proposed in SQ1 (method 400) compared to room temperature drying in SQ2 (method 500). Meanwhile, when printing and hot-air sintering are done alternatively as in SQ1, extra cooling time as that in SQ2 after the sintering is not needed, which reduces the processing time needed for SQ1 relative to SQ2.

FIG. 12(b) shows the measured resistance per unit area of the printed structures versus the number of layers taking either SQ1 or SQ2 before and after sintering. Comparing the resistances before and after sintering, for one layer and two layers, the resistance decreases more dramatically for SQ1 compared to that of SQ2. This is because evaporation of the liquid medium only takes place during the hot air sintering 404 in SQ1 whereas in SQ2, the evaporation takes place during both the drying 504 and the hot-air sintering 506 processes where the latter only contributes partially. For three and four layers in SQ2, the hot-air sintering 506 contributes more to the evaporation than the room temperature drying 504, which may be due to the increase in the accumulation of droplets when the number of printing layers increases, this lowering the efficiency of evaporation by drying. In SQ1 for three and four layers, the decreases are not significant which is due to the fact that a smooth conducting layer has been formed on the top and into the substrate, making the effect of adding conductive layers less significant.

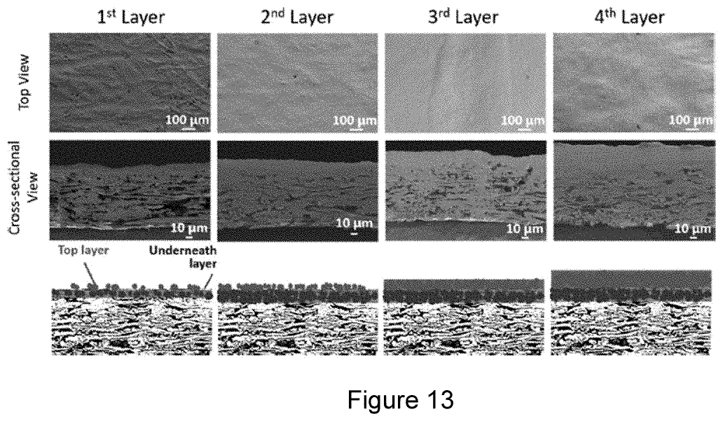

FIG. 13 shows the corresponding SEM images of the printed structures after sintering taking SQ2, the top views (the first row) and the cross-sectional views (the second row). For the structure with a single printed layer, the structure taking SQ2 shows similar morphology from the top view as that taking SQ1 shown in the first column in FIG. 8 where the pores are not fully filled up and fibers can be seen. Moreover, their top surface profiles in the cross-sectional views are similarly nonsmooth. Its resistance per unit area is relatively high as shown in FIG. 12(b). With only one layer of printing, the droplets in and on the substrate are unsaturated, which leads to the difficulty of forming a smooth conducting layer and thus a relatively high resistance. This is illustrated by the first sub-figure in the 3rd row in FIG. 13 which is similar to that in FIG. 8. In this case, the sintering sequence does not play a significant role. When two layers were printed taking sintering SQ1 and SQ2, it means that for SQ1, one layer was printed followed by sintering, then by the second layer of printing, and then by another round of sintering, whereas for SQ2, two layers were printed together, followed by 24-hour room temperature drying, then by hot-air sintering.

Comparing the 2nd columns in FIGS. 13 and 8, it is observed that, from the top views, the structure printed taking SQ1 is smoother with more pores and fibers well covered, and from the cross-sectional view, it has a smoother profile at the top compared to the structure printed taking SQ2. This is illustrated by the second sub-figure in the 3rd row in FIG. 13 which is different from that in FIG. 8. This leads to a higher resistance of the former structure compared to the latter structure as shown in FIG. 12(b). Taking SQ2 for sintering, as shown by the 3rd and 4th columns in FIG. 13, the smoothness is enhanced comparing the 3-layer structure to the 2-layer one, and similar between the 3-layer and the 4-layer structures.

The 3rd and 4th sub-figure in the 3rd row in FIG. 13 show illustration of these two cases which are similar in terms of the smoothness as those in FIG. 8.

For a comparison of the resistance of the printed structures taking these two approaches, as shown in FIG. 7, SQ1 leads to a lower resistance at each layer of printing. It is lowered by 60.7% after three layers and by 75.6% after four layers, compared to SQ2. In terms of the convergence rate of resistance versus the number of printed layers, also as shown in FIG. 7, SQ2 converges faster than SQ1 before two layers of printing whereas the convergence becomes slower for SQ2 compared to that of SQL This is because when the number of printing layers is low, room temperature dying in SQ2 is still effective to evaporate the liquid medium of the droplets for a formation of a conductive layer. However, when the number of printing layers increases, the droplets accumulate, which lowers the efficiency of evaporation by air drying and affects the smoothness of the metallic conducting layer. An immediate hot-air sintering after printing in SQ1, on the other hand, guarantees efficient evaporation. Comparing these two sintering sequences, SQ1 provides a lower resistance, i.e., a higher conductance, within a shorter time than SQ2. Besides SQ1 and SQ2, other sequences of sintering can be possible. To evaluate the efficiency of a sintering sequence, the efficiency of the evaporation of the liquid medium of the droplets that affect the speed and smoothness of the formation of a conducting layer is a key factor.

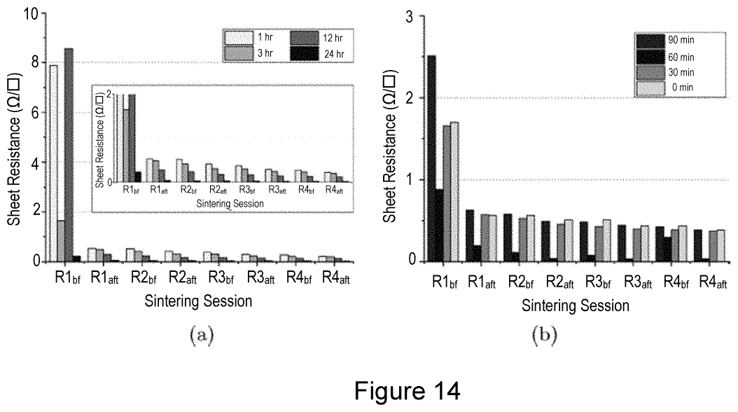

For the room temperature drying time (td) and cooling time (tc) in SQ2, FIG. 14 shows an investigation. FIG. 14(a) shows the measured sheet resistance of the printed structure at different numbers of sintering sections (before and after sintering) when td was set to be 1 h, 3 h, 12 h, and 24 h. The insert shows a zoomed-in view of the plot. The cooling time, tc, was set to be 60 min. As shown, at different number of sintering sections, before or after the sintering, 24 h of air drying leads to the lowest resistance. This is most likely due to a sufficient evaporation of the liquid medium of the droplets that allows the formation of a smooth metallic layer for conduction. For the investigation of the cooling time, tc was set to be 0 min, 30 min, 60 min, and 90 min while the dying time was set to be 24 h. FIG. 14(b) shows the measured sheet resistance of the printed structures with a different number of sintering sections, before and after the sintering. As can be seen in FIG. 14(b), 60 min is the optimal cooling time that leads to the lowest resistance at each number of sintering. It implies that 60 min of cooling works the best for forming a smooth conducting layer on top of the paper.

### The Effects of the Paper Substrate

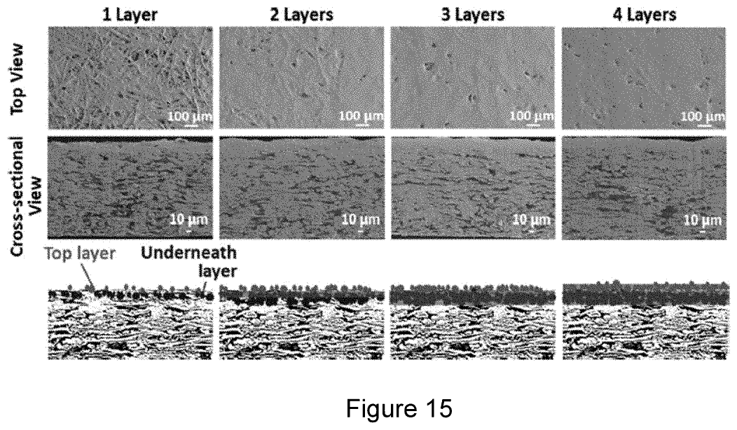

Different types of papers have different fiber size and morphology, and different porosities that affect the printing quality in the proposed AJP printing and sintering. FIGS. 6(e) and (f) show the SEM images of the top and side view of 160 gsm paper, respectively. They have different fiber size, morphology, and porosity compared to those of 80 gsm papers as shown in FIGS. 6(c) and (d). As can be seen, 160 gsm paper has bigger fibers and larger pores on the surface. FIG. 15 shows the SEM image of the printed structures on 160 gsm paper taking the proposed printing and sintering approach. Comparing the top views to those on 80 gsm papers in FIG. 13, the 160 gsm cases have less metallic particles filled up after each layer of printing, which results in less smoothness of the conducting layer (as shown in the side views in the second row and the illustrations in the third row in FIG. 13) and then a higher resistance as shown in FIG. 7. This is due to the bigger pore size of 160 gsm paper, and more layers of printing are necessary to lower the resistance further.

### The Effect of the Width of the Printed Pattern

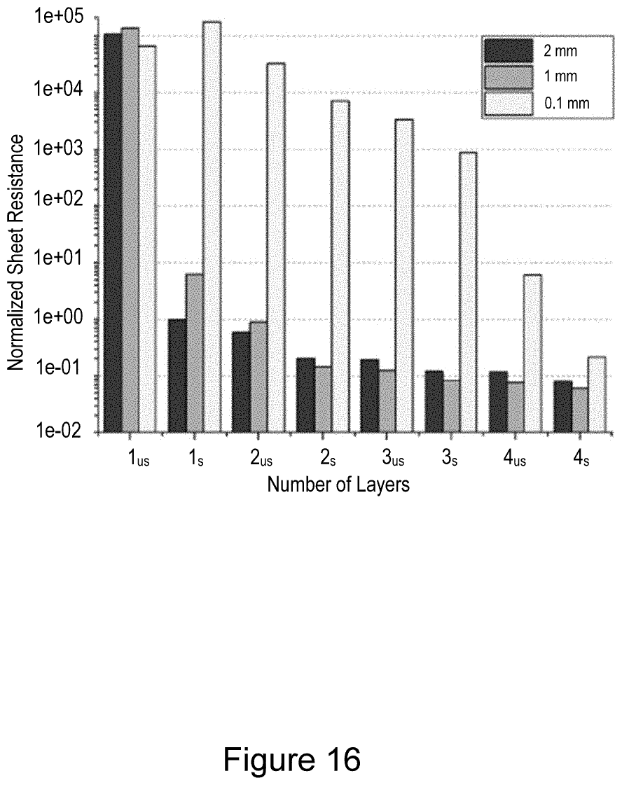

The effect of the width of the printed pattern was investigated. The test strips with widths of 2 mm, 1 mm, and 0.1 mm were printed and sintered with the proposed fabrication procedure. FIG. 16 shows the values of all the sheet resistances normalized to that of the sintered first layer of the 2 mm test strip. As FIG. 16 shows, the 1 mm pattern has similar conductivity as that of the 2 mm one, whereas the 0.1 mm printed structure exhibits a considerably different trend of change of the conductivity. Although the 0.1 mm strip started with a comparable sheet resistance to the other two cases, its resistance decreases lag behind them, and the final value is about 2.68 times higher than that of the 2 mm case. This implies that the capillary force of the inter-fiber pores may not function well when the pattern size decreases, as the area of the pattern may not cover fully the area of the pores. For the parameters in this proposed printing approach, although it works the best for structures with mm-scales, further optimizations are needed for micrometer-scale patterns for a high conductivity.

Many modifications will be apparent to those skilled in the art without departing from the scope of the present invention.

Throughout this specification, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

1. A method of fabricating at least one electronic circuit component, comprising:
(i) patterning a conductive material on a flexible fibrous substrate by aerosol jet printing in a pattern corresponding to said at least one electronic circuit component; and
(ii) sintering the conductive material by hot air sintering.

2. A method according to claim 1, wherein steps (i) and (ii) are performed iteratively.

3. A method according to claim 2, wherein steps (i) and (ii) are performed for at least 3 iterations.

4. A method according to claim 1, wherein said sintering is conducted at a temperature lower than a melting temperature of particles of the conductive material.

5. A method according to claim 4, wherein said sintering is conducted at less than about 130° C.

6. A method according to claim 5, wherein said sintering is conducted at about 80° C.

7. A method according to claim 1, wherein the flexible fibrous substrate is paper.

8. A method according to claim 7, wherein the paper is cellulose fibre paper.

9. A method according to claim 1, wherein said patterning comprises applying a plurality of layers of the conductive material.

10. A method according to claim 9, wherein said patterning comprises applying at least three layers of the conductive material.

11. A method according to claim 1, comprising, after said sintering, room temperature drying and/or room temperature cooling of the substrate.

12. A method according to claim 11, comprising multiple cycles of sintering and room temperature drying and/or room temperature cooling.

13. A system for fabricating at least one electronic circuit component, comprising:
an aerosol jet printing device;
a hot air sintering module; and
at least one controller in communication with the aerosol jet printing device and the sintering platform;
wherein the at least one controller is configured to:
cause the aerosol jet printing device to perform a printing operation comprising patterning a conductive material on a flexible fibrous substrate in a pattern corresponding to said at least one electronic circuit component; and
cause the hot air sintering module to perform a sintering operation to sinter the conductive material.

14. A system according to claim 13, wherein the at least one controller is configured for iterative performance of the printing and sintering operations.

15. A system according to claim 14, wherein the at least one controller is configured for at least 3 iterations of the printing and sintering operations.

16. A system according to claim 13, wherein said sintering operation is conducted at a temperature lower than a melting temperature of particles of the conductive material.

17. A system according to claim 16, wherein said sintering operation is conducted at less than about 130° C.

18. A system according to claim 17, wherein said sintering operation is conducted at about 80° C.

19. A system according to claim 13, wherein said patterning operation comprises applying a plurality of layers of the conductive material.

20. A system according to claim 19, wherein said patterning operation comprises applying at least three layers of the conductive material.
